(19) United States
(12) Patent Application Publication
(10) Pub. No.: US 2026/0155828 A1
(43) Pub. Date: Jun. 4, 2026

(54) ANALOGUE TO DIGITAL CONVERTER AND METHOD FOR CONTROLLING THE SAME

(71) Applicant: Renesas Electronics Corporation, Tokyo (JP)

(72) Inventor: Sougo OOKAWA, Tokyo (JP)

(21) Appl. No.: 19/399,141

(22) Filed: Nov. 24, 2025

(30) Foreign Application Priority Data
Dec. 4, 2024 (JP) 2024-210898

(51) Int. Cl. H03M 1/06

(52) U.S. Cl. CPC H03M 1/0604

(57) ABSTRACT

The analogue to digital converter outputs a conversion value obtained by performing analogue to digital conversion on an input signal. The non-volatile memory stores a plurality of correction values. The correction circuit selects, in response to a status affecting an offset in the conversion value of the analogue to digital converter, a correction value corresponding to the status from among the plurality of correction values as a selected correction value, and outputs an output value where the offset in the conversion value is corrected based on the selected correction value.

### CROSS-REFERENCE TO RELATED APPLICATIONS

The disclosure of Japanese Patent Application No. 2024-210898 filed on December 4, 2024 including the specification, drawings and abstract is incorporated herein by reference in its entirety.

### BACKGROUND

The present disclosure relates to a semiconductor device, and a method and a program for correcting a conversion value of an analogue to digital converter which are suitable for use in, for example, a semiconductor device with a non-volatile memory.

A microcomputer incorporated into a semiconductor device is provided with an analogue to digital converter (hereinafter also referred to as A/D converter). The A/D converter is known to introduce an offset in conversion results caused by factors such as operation frequency and environmental temperature. While it is conceivable to define semiconductor device specifications based on usage conditions, its complexity makes it impractical. As a result, a case may arise where the usage of the semiconductor device needs to be determined by assuming the worst-case scenario caused by the usage conditions. In such a case, inherent performance of the semiconductor device may be constrained.

In this regard, there is provided a method in which the offset amount of the A/D converter mounted on the semiconductor device is measured, and the measured offset amount is added or subtracted from an output of the A/D converter to correct the output of the A/D converter. In such a method, the measured offset amount of the A/D converter is stored in a register mounted on the semiconductor device. The offset amount read from the register is then added or subtracted from the output of the A/D converter according to the usage conditions of the semiconductor device to correct the output of the A/D converter.

There are disclosed techniques listed below.

[Patent Document 1] Japanese Unexamined Patent Application Publication No. 2014-209390

Patent Document 1 also discloses a method in which settings of a processing unit are switched according to the non-volatile memory mounted on the semiconductor device.

### SUMMARY

However, in the above-described general methods, the output offset of the A/D converter caused by a connection between the semiconductor device and other devices is corrected. Therefore, measurement of the offset amount and determination of the correction value are performed by the user of the semiconductor device. Therefore, there may be a case where general methods cannot be applied when determining the semiconductor device specifications prior to providing the device to the user.

Other problems and novel features will become clear from the description of the present specification and accompanying drawings.

According to one embodiment, there is provided a semiconductor device comprising an analogue to digital converter configured to output a conversion value obtained by performing analogue to digital conversion on an input signal, a non-volatile memory configured to store a plurality of correction values, and a correction circuit configured to select, in response to a status affecting an offset in the conversion value of the analogue to digital converter, a correction value corresponding to the status from among a plurality of correction values as a selected correction value, and to output an output value in which the offset in the conversion value is corrected based on the selected correction value.

According to one embodiment, there is provided a method for correcting a conversion value of an analogue to digital converter. The method includes the steps of outputting a conversion value obtained by performing analogue to digital conversion on an input signal, selecting, in response to a status affecting an offset in the conversion value, a correction value corresponding to the status from among a plurality of correction values stored in a non-volatile memory, and outputting an output value in which the offset in the conversion value is corrected based on the selected correction value.

According to one embodiment, there is provided a program configured to cause a computer to perform a process of selecting, in response to a status affecting an offset in a conversion value obtained by performing analogue to digital conversion on an input signal using an analogue to digital converter, a correction value corresponding to the status from among a plurality of correction values stored in a non-volatile memory, and a process of outputting an output value in which the offset in the conversion value is corrected based on the selected correction value.

According to one embodiment, it is possible to provide a semiconductor device configured to automatically correct a conversion value of the analogue to digital converter, and a method and a program for correcting the conversion value of the analogue to digital converter.

### BRIEF DESCRIPTION OF THE DRAWINGS

FIG. 1 is a block diagram schematically showing a configuration of a semiconductor device according to a first embodiment.

FIG. 2 is a sequence diagram showing an operation of the semiconductor device according to the first embodiment.

FIG. 3 is a block diagram showing the configuration of the semiconductor device according to the first embodiment in more detail.

FIG. 4 is a block diagram schematically showing a configuration of a semiconductor device according to a second embodiment.

FIG. 5 is a block diagram schematically showing a configuration of a semiconductor device according to a third embodiment.

FIG. 6 is a block diagram schematically showing a configuration example of a main part of an A/D converter.

FIG. 7 is a block diagram schematically showing a configuration of a semiconductor device according to a fourth embodiment.

FIG. 8 is a block diagram schematically showing a configuration of a semiconductor device according to a fifth embodiment.

FIG. 9 is a block diagram schematically showing a configuration of a semiconductor device according to a sixth embodiment.

FIG. 10 is a block diagram schematically showing a configuration of a semiconductor device according to a seventh embodiment.

FIG. 11 is a diagram showing a configuration example of a computer for realizing the semiconductor device.

### DETAILED DESCRIPTION

The following is a description of embodiments with reference to the drawings. In each of the drawings, identical elements are denoted by an identical reference sign, and redundant descriptions are omitted as appropriate.

### FIRST EMBODIMENT

FIG. 1 is a block diagram schematically showing a configuration of a semiconductor device according to a first embodiment. A semiconductor device 100 has an analogue to digital converter 1, a non-volatile memory 11, and a correction circuit 21. Hereinafter, the analogue to digital converter will also be referred to as an A/D converter for simplicity.

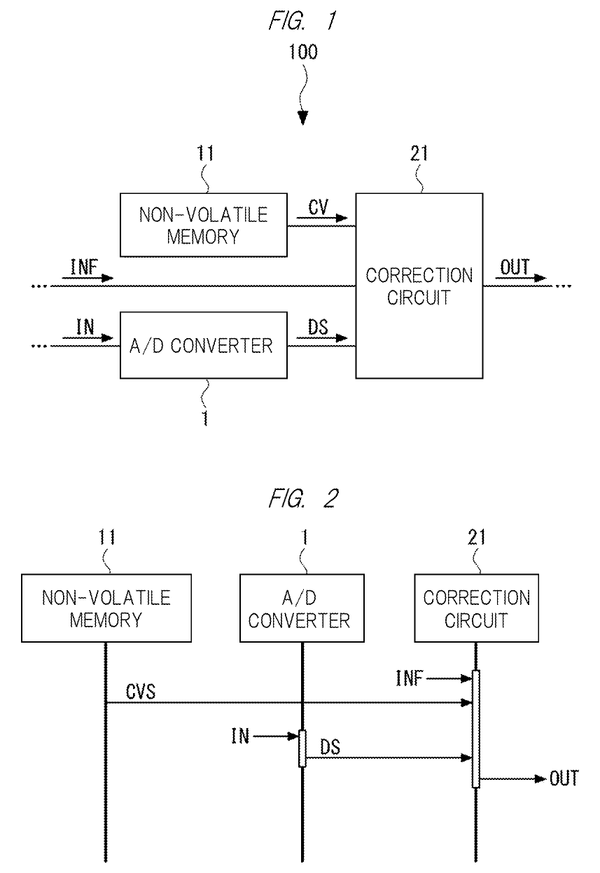

A configuration of the semiconductor device 100 will now be described with reference to an operational flow. FIG. 2 is a sequence diagram showing an operation of the semiconductor device according to the first embodiment.

### STEP S1

The A/D converter 1 converts a data signal IN which is an input analogue signal into a conversion value DS which is a digital value. The A/D converter 1 outputs the conversion value DS to the correction circuit 21.

The non-volatile memory 11 stores a plurality of correction values used to correct an offset in the conversion value DS of the A/D converter 1. The plurality of correction values stored in the non-volatile memory 11 are correction values set in advance so as to correspond to an operating status of the semiconductor device 100.

### STEP S2

The correction circuit 21 receives the plurality of correction values from the non-volatile memory 11. In addition, the correction circuit 21 receives status information INF indicating the operating status of the semiconductor device 100. In FIG. 1, the plurality of correction values are represented by a reference sign CV for simplicity. The correction circuit 21 selects a correction value CVS corresponding to the operating condition of the semiconductor device 100 indicated by the status information INF from the plurality of correction values CV. Then, the correction circuit 21 corrects the conversion value DS of the A/D converter 1 using the selected correction value CVS, and outputs a corrected output value OUT. Hereinafter, the correction value selected by the correction circuit will also be referred to as the selected correction value.

The configuration and operation of the semiconductor device 100 will now be described with reference to specific examples. In the present embodiment, an example of correcting the offset in the conversion value DS of the A/D converter 1 depending on the operation frequency of a circuit mounted on the semiconductor device 100 and the A/D converter 1 is described.

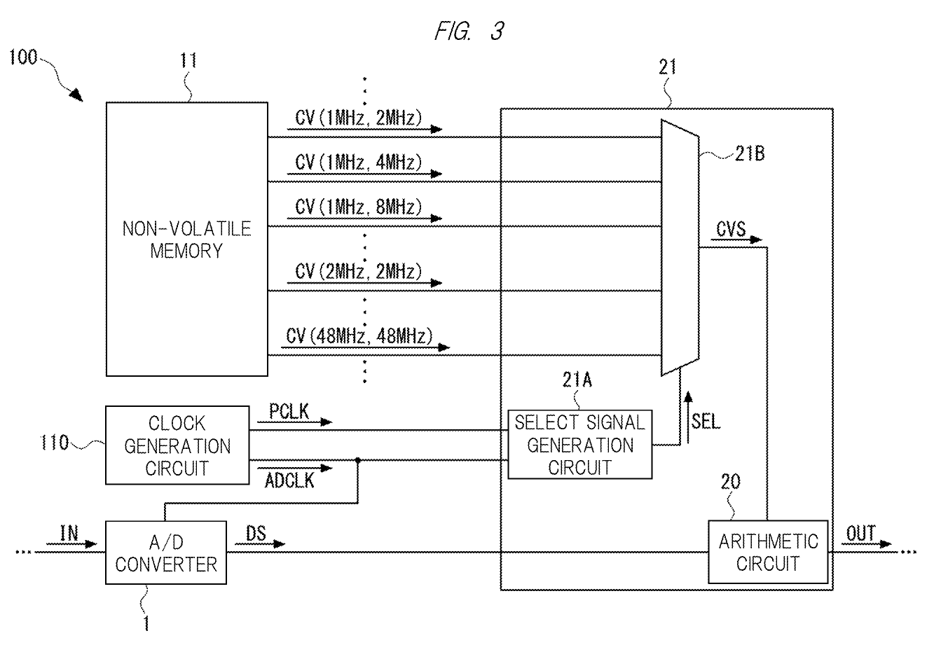

FIG. 3 is a block diagram showing the configuration of the semiconductor device according to the first embodiment in more detail. The semiconductor device 100 is provided with a clock generation circuit 110. The clock generation circuit 110 outputs a clock signal ADCLK specifying an A/D conversion operation frequency of the A/D converter 1 to the A/D converter 1. In addition, the clock generation circuit 110 outputs a reference clock signal PCLK. Circuits mounted on the semiconductor device 100 with the exception of at least the A/D converter 1 operate in response to the reference clock signal PCLK output by the clock generation circuit 110. Note that, in FIG. 3, the clock generation circuit 110 generates both the clock signal ADCLK and the reference clock signal PCLK, but this is merely an example. For example, the clock signal ADCLK and the reference clock signal PCLK may be generated by different clock signal generation means provided in the semiconductor device 100.

In the semiconductor device 100, the A/D converter 1 performs A/D conversion in response to the clock signal ADCLK that differs from the reference clock signal PCLK. The conversion value DS of the A/D converter 1 includes the offset caused by various factors. The amount of offset in the conversion value DS is known to occur depending on, for example, a combination of the reference clock and the A/D conversion frequency. In such a case, the amount of offset in the conversion value DS changes in accordance with a change in the combination of the reference clock and the A/D conversion frequency. Note that, while the combination of the reference clock and the A/D conversion frequency is given as an example of a factor causing offset in the conversion value DS, the factors causing the offset are not limited to these.

Therefore, the semiconductor device 100 according to the present embodiment corrects the offset in the conversion value DS based on both a frequency f_{AD} of the clock signal ADCLK which is the A/D conversion operation frequency, and a frequency f_{P} of the reference clock signal PCLK.

The non-volatile memory 11 stores the plurality of correction values CV corresponding to the frequency f_{AD} of the clock signal ADCLK and the frequency f_{P} of the reference clock signal PCLK. Hereinafter, the frequency f_{AD} of the clock signal ADCLK and the frequency f_{P} of the reference clock signal PCLK will also be referred to as operation frequencies of the semiconductor device 100 for simplicity of explanation. In addition, the frequency f_{AD} of the clock signal ADCLK will also be referred to as a conversion operation frequency of the A/D converter 1.

The correction circuit 21 has an arithmetic circuit 20, a select signal generation circuit 21A, and a selector 21B.

The select signal generation circuit 21A receives the clock signal ADCLK and the reference clock signal PCLK. Note that the clock signal ADCLK and the reference clock signal PCLK correspond to the above-described status information INF. The select signal generation circuit 21A generates a select signal SEL that controls an operation of the selector 21B based on the frequencies of the clock signal ADCLK and the reference clock signal PCLK. The select signal generation circuit 21A may determine the frequency f_{AD}of the clock signal ADCLK and the frequency f_{P} of the reference clock signal PCLK based on multiplication and division settings of the clock generation circuit 110. However, the method for determining the frequency f_{AD} of the clock signal ADCLK and the frequency f_{P} of the reference clock signal PCLK in the select signal generation circuit 21A is merely an example. The select signal generation circuit 21A may use various frequency determination methods to determine the frequency f_{AD} of the clock signal ADCLK and the frequency f_{P} of the reference clock signal PCLK. The select signal generation circuit 21A outputs the generated select signal SEL to the selector 21B.

The selector 21B selects a correction value corresponding to the combination of the frequencies of the clock signal ADCLK and the reference clock signal PCLK indicated by the select signal SEL from among the plurality of correction values stored in the non-volatile memory 11. For example, when the frequency of the clock signal ADCLK is 8 MHz, and the frequency of the reference clock signal PCLK is 24 MHz, the selector 21B selects the correction value CV (8 MHz, 24 MHz) corresponding to the combination of the frequencies of the clock signal ADCLK and the reference clock signal PCLK, and outputs the value as the selected correction value CVS to the arithmetic circuit 20.

The arithmetic circuit 20 corrects the conversion value DS based on the selected correction value CVS from the selector 21B. The arithmetic circuit 20 may be configured as, for example, an addition/subtraction circuit. In such a case, the selector 21B adds or subtracts the selected correction value CVS to or from the conversion value DS to correct the conversion value DS. The arithmetic circuit 20 then outputs the value obtained by the correction as the output value OUT.

Thus, according to the semiconductor device 100, the offset amount in the conversion value of the A/D converter can be automatically corrected by a suitable correction value corresponding to the conversion operation frequency of the A/D converter and the frequency of the reference clock signal of the semiconductor device 100. Thus, the semiconductor device 100 can obtain the desired output value as an A/D conversion result of the A/D converter for the input signal, regardless of the conversion operation frequency of the A/D converter and the frequency of the reference clock signal of the semiconductor device 100.

The selection of the correction value may be performed at, for example, startup of the semiconductor device 100. Selecting the correction value prior to the start of operation of the A/D converter after startup allows the offset amount in the output value to be appropriately corrected from the start of operation of the A/D converter.

In addition, the selection of the correction value may be performed during the operation of the semiconductor device 100. For example, it is anticipated that the combination of frequencies of the clock signal ADCLK and the reference clock signal PCLK may vary after the semiconductor device 100 starts operating, such as when the user changes the frequency settings. In such a case, the select signal generation circuit 21A detects a variation in the combination of frequencies of the clock signal ADCLK and the reference clock signal PCLK, and reflects the detection result to the select signal SEL. As a result, the selector 21B can select, in response to the select signal SEL, a correction value corresponding to the combination of the frequencies of the clock signal ADCLK and the reference clock signal PCLK after the variation. Thus, according to the semiconductor device 100, the offset in the conversion value of the A/D converter can be appropriately corrected in response to the latest operating status.

The correction of the offset in the conversion value of the A/D converter in the semiconductor device 100 is automatically executed as described above without the user of the semiconductor device 100 having to be particularly aware of it. Thus, unlike the general method described above, the user of the semiconductor device does not have to perform the task of determining the correction value of the offset amount. Therefore, the semiconductor device 100 can be more easily introduced by the user, and the amount of work required for introducing the device can be reduced.

Thus, a maximum performance of the semiconductor device 100 can be presented to the user as the specifications of the semiconductor device 100 according to the operating status. As a result, unlike in the case of the general method, the specifications of the semiconductor device 100 can be determined based on the performance that the semiconductor device 100 can inherently achieve, without restricting the specifications presented to the user.

In addition, the non-volatile memory 11 of the semiconductor device 100 can utilize an optional memory that is generally provided in the semiconductor device and can store various additional data. Therefore, the semiconductor device 100 according to the first embodiment can be realized without adding any special hardware configurations to the general semiconductor device. As a result, the semiconductor device according to the embodiment can be easily realized at low cost by utilizing an existing semiconductor device.

### SECOND EMBODIMENT

In the first embodiment, a semiconductor device that corrects the offset in the conversion value DS depending on the operation frequency of the semiconductor device has been described. However, factors causing the offset in the conversion value DS are not limited to the operation frequency of the semiconductor device. For example, it is conceivable that the offset in the conversion value DS may vary with changes in the temperature of the semiconductor device. Therefore, in a second embodiment, a semiconductor device that corrects the offset in the conversion value of the A/D converter in accordance with the environmental temperature is described.

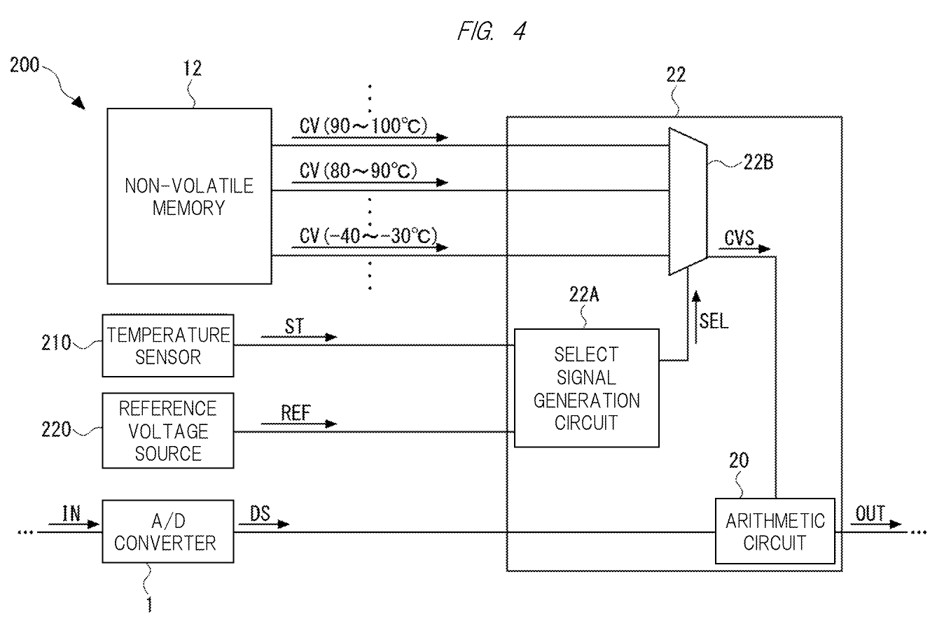

FIG. 4 is a block diagram schematically showing a configuration of a semiconductor device according to the second embodiment. A semiconductor device 200 according to the second embodiment has a configuration in which the non-volatile memory 11 and the correction circuit 21 of the semiconductor device 100 are respectively replaced with a non-volatile memory 12 and a correction circuit 22.

In addition, the semiconductor device 200 differs from the semiconductor device 100 in that an input to a select signal generation circuit 22A is replaced with a temperature sensor 210 and a reference voltage source 220 from the clock generation circuit 110. Note that in FIG. 4, the clock generation circuit 110 is omitted for simplicity.

The temperature sensor 210 measures the temperature of the semiconductor device 200 at a predetermined position. The temperature sensor 210 then outputs a temperature signal ST indicating the measured environmental temperature TMP to the correction circuit 22. The temperature signal ST is, for example, a voltage signal representing the temperature by voltage.

The reference voltage source 220 outputs a reference voltage REF indicating the reference temperature for comparison with the temperature signal ST to the correction circuit 22.

The non-volatile memory 12 stores a plurality of correction values corresponding to the temperature TMP. In FIG. 4, for example, the correction values CV (TL to TH) are set for each temperature range in 10-degree increments ranging from a lower limit temperature to an upper limit temperature TH.

The correction circuit 22 has the select signal generation circuit 22A and a selector 22B respectively corresponding to the select signal generation circuit 21A and the selector 21B of the correction circuit 21. Note that the arithmetic circuit 20 in correction circuit 22 is the same as the arithmetic circuit 20 in the correction circuit 21.

The select signal generation circuit 22A compares the temperature signal ST and the reference voltage REF, and detects the temperature TMP indicated by the temperature signal ST. Note that the temperature signal ST and the reference voltage REF correspond to the above-described status information INF. Based on the detected temperature TMP, the select signal generation circuit 22A outputs the select signal SEL indicating the correction value to be selected from among the plurality of correction values output by the non-volatile memory 12 to the selector 22B.

The selector 22B selects the correction value corresponding to the temperature TMP indicated by the select signal SEL from among the plurality of correction values stored in the non-volatile memory 12. For example, when the temperature TMP is 28°C, the correction value CV (20°C to 30°C) corresponding to the temperature range 20°C≤T<30°C is selected as the selected correction value CVS and is output to the arithmetic circuit 20.

An operation of the arithmetic circuit 20 in the correction circuit 22 is the same as the operation in the correction circuit 21, and thus, descriptions thereof are omitted.

Thus, according to the semiconductor device 200, the offset in the conversion value of the A/D converter can be automatically corrected by a suitable correction value corresponding to the environmental temperature. Thus, the semiconductor device 200 can obtain the desired output value OUT after correction as the A/D conversion result of the A/D converter for the input signal, regardless of the environmental temperature.

Other advantages of the semiconductor device 200 are the same as those of the semiconductor device 100, and thus, redundant descriptions thereof are omitted.

### THIRD EMBODIMENT

In the above-described embodiments, a semiconductor device that corrects the offset in the conversion value DS depending on the operation frequency or the environmental temperature of the semiconductor device has been described. However, factors causing the offset in the conversion value DS are not limited to the operation frequency or the environmental temperature of the semiconductor device. For example, it is conceivable that the offset in the conversion value DS may vary depending on an input signal IN. Therefore, in a third embodiment, a semiconductor device that corrects the offset that varies depending on the input signal IN is described. Note that the conversion value DS varies depending on the input signal IN and a reference voltage of the A/D converter 1. However, a case where the reference voltage of the A/D converter 1 is a predetermined constant voltage is described.

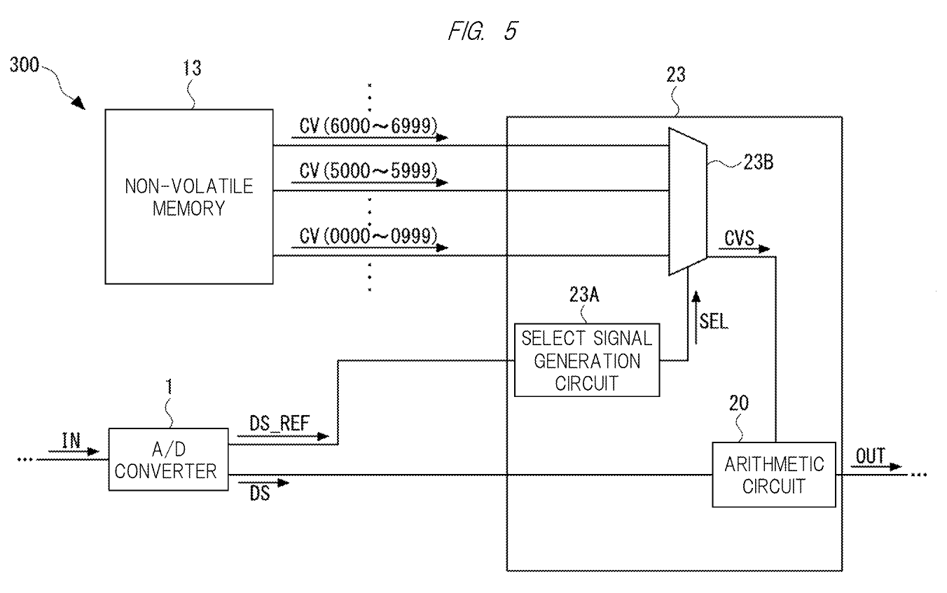

FIG. 5 is a block diagram schematically showing a configuration of a semiconductor device according to the third embodiment. A semiconductor device 300 according to the third embodiment has a configuration in which the non-volatile memory 11 and the correction circuit 21 of the semiconductor device 100 are respectively replaced with a non-volatile memory 13 and a correction circuit 23. In addition, the semiconductor device 300 differs from the semiconductor device 100 in that an input from the clock generation circuit 110 to a select signal generation circuit 23A has been removed. Note that in FIG. 5, the clock generation circuit 110 is omitted for simplicity.

The A/D converter 1 outputs the conversion value DS constituting a conversion code after A/D conversion is performed to both the arithmetic circuit 20 and the correction circuit 23. Here, for the sake of distinction, a conversion value output from the A/D converter 1 to the arithmetic circuit 20 is referred to as a conversion value DS_REF. Note that the conversion value DS_REF corresponds to the above-described status information INF.

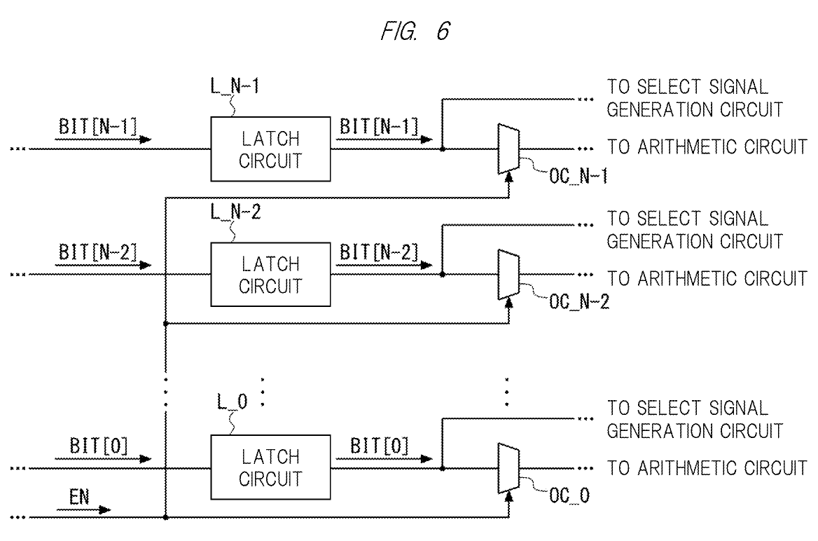

At this time, the A/D converter 1 may output the conversion code to the correction circuit 23 prior to outputting the conversion value DS to the arithmetic circuit 20. FIG. 6 is a block diagram schematically showing a configuration example of a main part of the A/D converter. FIG. 6 shows an example where the A/D converter 1 is configured as a successive approximation type A/D converter, and converts the input signal IN into an N-bit conversion code. In such a case, the A/D conversion of the input signal IN is performed sequentially one bit at a time, from the most significant bit (MSB) BIT [N-1] to the least significant bit (LSB) BIT [0]. At this time, conversion results of each bit are held in latch circuits L_N-1 to L_0. After all bits have been converted, the A/D converter 1 outputs, in accordance with a transition of an output enable signal EN provided to output circuits OC_N-1 to OC_0, the conversion values DS to the arithmetic circuit 20 in bulk from the output circuits OC_N-1 to OC_0.

In this regard, the A/D converter 1 shown in FIG. 6 sequentially outputs the conversion results of each bit held in the latch circuits L_N-1 to L_0 to the correction circuit 23, regardless of the output enable signal EN. In such a case, before the arithmetic circuit 20 receives the conversion value DS from the A/D converter 1, the correction circuit 23 can be notified of the conversion value DS_REF. As a result, the correction circuit 23 can provide the arithmetic circuit 20 with the selected correction value CVS corresponding to the conversion value DS_REF prior to correcting the conversion value DS in the arithmetic circuit 20.

The non-volatile memory 13 stores a plurality of correction values corresponding to the conversion value DS_REF. In FIG. 5, for example, the correction values CV (MIN to MAX) are set for each range in increments of 1000 where the conversion value DS_REF ranges from a lower limit value MIN to an upper limit value MAX.

The correction circuit 23 has the select signal generation circuit 23A and a selector 23B respectively corresponding to the select signal generation circuit 21A and the selector 21B of the correction circuit 21. Note that the arithmetic circuit 20 in the correction circuit 23 is the same as the arithmetic circuit 20 in the correction circuit 21.

Based on the conversion value DS_REF, the select signal generation circuit 23A outputs the select signal SEL indicating the correction value to be selected from among the plurality of correction values output by the non-volatile memory 12 to the selector 23B.

The selector 23B selects the correction value corresponding to the conversion value DS_REF indicated by the select signal SEL from among the plurality of correction values stored in the non-volatile memory 13. For example, when the conversion code is 5265, the correction value CV (5000 to 5999) is selected as the selected correction value CVS and is output to the arithmetic circuit 20.

An operation of the arithmetic circuit 20 in the correction circuit 23 is the same as the operation of the arithmetic circuit 20 in the correction circuit 21, and thus, descriptions thereof are omitted.

In the present embodiment, the case where the reference voltage of the A/D converter 1 is a predetermined constant voltage has been described for simplicity of explanation, but this is merely an example. In general, the reference voltage of the A/D converter is changeable, and the value of the reference voltage varies depending on the user. That is, even if the input signal IN is constant, the conversion code for correcting the offset may differ depending on the reference voltage. Therefore, instead of using the conversion value DS_REF, the reference voltage of the A/D converter 1 can be input to the select signal generation circuit 23A to allow the select signal generation circuit 23A determine the reference voltage. Thus, the select signal generation circuit 23A may output the select signal SEL corresponding to the A/D converter 1. Furthermore, by storing the correction value CV corresponding to the reference voltage in the non-volatile memory 13, the selector 21B may select the correction value CV corresponding to the reference voltage. For determining the reference voltage of the A/D converter 1, if there is a holding means such as a register within the semiconductor device 300 that holds information indicating the reference voltage of the A/D converter 1, the information indicating the reference voltage of the A/D converter 1 may be input from the holding means to the select signal generation circuit 23A.

By combining these, according to the semiconductor device 300, the offset in the conversion value of the A/D converter can be automatically corrected by a suitable correction value corresponding to the offset that varies in response to the input signal IN. Thus, the semiconductor device 300 can appropriately correct the offset that varies depending on the input signal IN to obtain the desired output value OUT.

Other advantages of the semiconductor device 300 are the same as those of the semiconductor devices according to the above-described embodiments, and thus, redundant descriptions thereof are omitted.

### FOURTH EMBODIMENT

In the above-described embodiments, one type of parameter among the operation frequency of the semiconductor device, the environmental temperature, and the conversion value output by the A/D converter was used as the operating status of the semiconductor device for selecting the correction value. However, depending on usage of the semiconductor device, there may be a case where it is desirable to select a correction value by simultaneously referencing a plurality of parameters to more accurately correct the conversion value. Therefore, in a fourth embodiment, a semiconductor device that selects a correction value by referencing two types of information indicating operating statuses that are independent of each other is described.

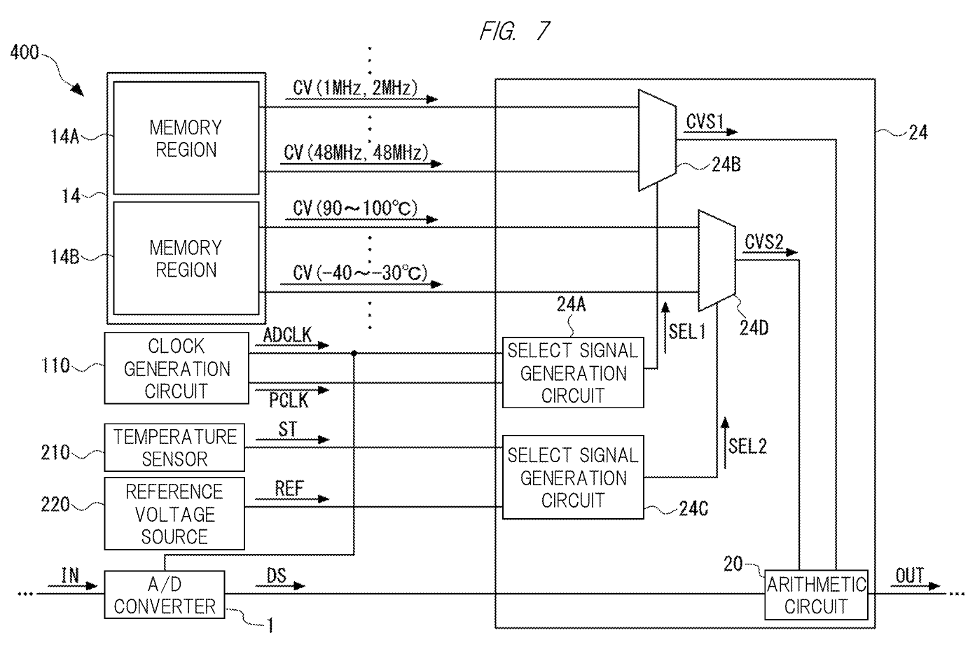

FIG. 7 is a block diagram schematically showing a configuration of a semiconductor device according to the fourth embodiment. A semiconductor device 400 corrects the conversion value DS by using two types of correction values respectively corresponding to two types of operating statuses by referencing information indicating two types of operating statuses that are independent of each other.

The semiconductor device 400 has a configuration in which the non-volatile memory 11 and the correction circuit 21 of the semiconductor device 100 are respectively replaced with a non-volatile memory 14 and a correction circuit 24.

In addition, the semiconductor device 400 differs from the semiconductor device 100 in that the temperature sensor 210 and the reference voltage source 220 which are the same as those of the semiconductor device 200 are further provided.

The non-volatile memory 14 has at least a memory region 14A for storing the correction value set so as to correspond to the operation frequency as in the first embodiment, and a memory region 14B for storing the correction value set so as to correspond to the temperature as in the second embodiment.

The correction circuit 24 has a select signal generation circuit 24A, a selector 24B, a select signal generation circuit 24C, and a selector 24D. Note that the arithmetic circuit 20 in the correction circuit 24 is the same as the arithmetic circuit 20 in the correction circuit 21.

The select signal generation circuit 24A and the selector 24B are respectively the same as the select signal generation circuit 21A and the selector 21B according to the first embodiment, and thus, redundant descriptions thereof are omitted. Note that in FIG. 7, for the sake of distinction, a select signal output from the select signal generation circuit 24A to the selector 24B is referred to as a select signal SEL1. In addition, a selected correction value selected by the selector 24B is referred to as a selected correction value CVS1.

The select signal generation circuit 24C and the selector 24D are respectively the same as the select signal generation circuit 22A and the selector 22B according to the second embodiment, and thus, redundant descriptions thereof are omitted. Note that in FIG. 7, for the sake of distinction, a select signal output from the select signal generation circuit 24C to the selector 24D is referred to as a select signal SEL2. In addition, a selected correction value selected by the selector 24D is referred to as a selected correction value CVS2.

In the present embodiment, the clock signal ADCLK, the reference clock signal PCLK, the temperature signal ST, and the reference voltage REF correspond to the above-described status information INF.

Therefore, according to the semiconductor device 400, the selected correction value CVS1 corresponding to the operation frequency of the semiconductor device 400 and the selected correction value CVS2 corresponding to the environmental temperature can be selected from among the plurality of correction values stored in the non-volatile memory 14. Then, the arithmetic circuit 20 can appropriately correct the offset amount in the conversion value DS by using the selected correction value CVS1 corresponding to the operation frequency of the semiconductor device 400 and the selected correction value CVS2 corresponding to the environmental temperature in combination to correct the conversion value DS of the A/D converter 1.

Other advantages of the semiconductor device 400 are the same as those of the semiconductor devices according to the above-described embodiments, and thus, redundant descriptions thereof are omitted.

### FIFTH EMBODIMENT

In the fourth embodiment, an example in which the offset corresponding to the operation frequency of the semiconductor device and the offset corresponding to the environmental temperature are independent of each other has been described. However, in an actual semiconductor device, effects of the operation frequency and the environmental temperature on the offset are inseparable and may not be independent of each other. In such a case, it is inappropriate to separately set the correction values corresponding to the operation frequency and the environmental temperature as in the fourth embodiment.

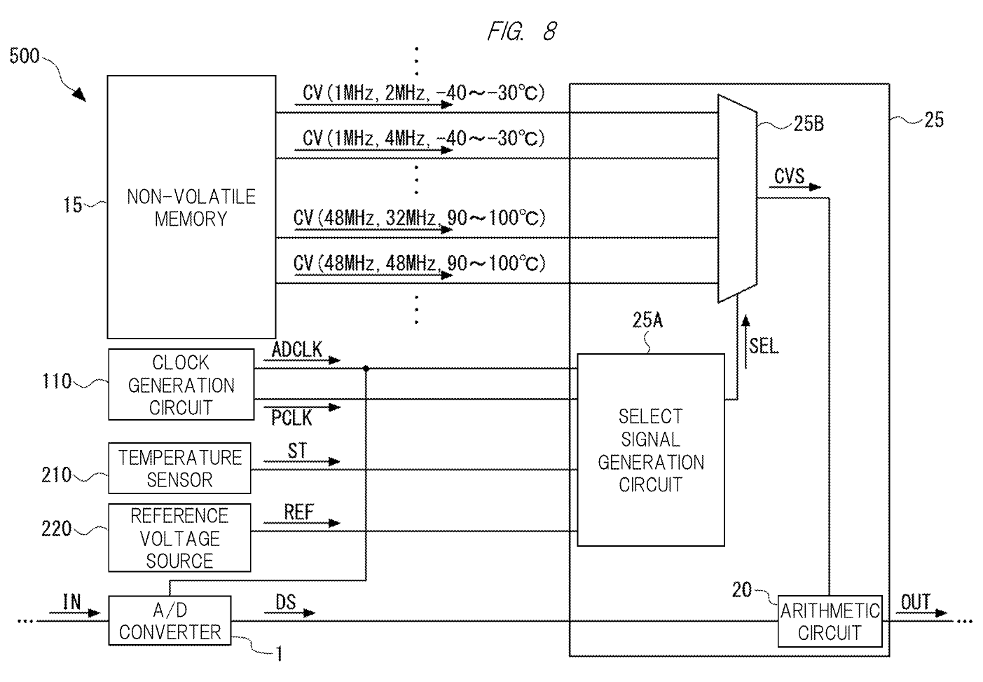

Therefore, in the present embodiment, a semiconductor device that selects a single correction value by referencing information indicating two types of operating statuses that are not independent of each other is described. FIG. 8 is a block diagram schematically showing a configuration of a semiconductor device according to a fifth embodiment.

A semiconductor device 500 according to the fifth embodiment has a configuration in which the non-volatile memory 14 and the correction circuit 24 of the semiconductor device 400 are respectively replaced with a non-volatile memory 15 and a correction circuit 25.

The non-volatile memory 15 stores a plurality of correction values set in advance so as to correspond to a combination of the frequency f_{AD} of the clock signal ADCLK, the frequency f_{P} of the reference clock signal PCLK, and the temperature TMP. In FIG. 8, the correction value corresponding to the frequency f_{AD} [MHz] of the clock signal ADCLK, the frequency f_{P} [MHz] of the reference clock signal PCLK, and the temperature TMP is denoted as C (f_{AD}, f_{P}, TL to TH).

The correction circuit 25 has a select signal generation circuit 25A and a selector 25B. Note that the arithmetic circuit 20 in the correction circuit 25 is the same as the arithmetic circuit 20 in the correction circuit 21.

The select signal generation circuit 25A receives the clock signal ADCLK, the reference clock signal PCLK, the temperature signal ST, and the reference voltage REF. Then, the select signal generation circuit 25A generates the select signal SEL that controls an operation of the selector 25B based on the frequency f_{AD} of the clock signal ADCLK, the frequency f_{P} of the reference clock signal PCLK, and the temperature TMP. The select signal generation circuit 25A outputs the generated select signal SEL to the selector 25B.

The selector 25B selects a correction value corresponding to the combination of the frequency f_{AD} of the clock signal ADCLK, the frequency f_{P} of the reference clock signal PCLK, and the temperature TMP indicated by the select signal SEL from among the plurality of correction values stored in the non-volatile memory 15. Here, an example is assumed where the frequency of the clock signal ADCLK is 8MHz, the frequency of the reference clock signal PCLK is 24MHz, and the temperature TMP is 28°C. In such a case, the selector 25B outputs the correction value C (8MHz, 24MHz, 20°C to 30°C) corresponding to these values as the selected correction value CVS to the arithmetic circuit 20.

In the present embodiment, the clock signal ADCLK, the reference clock signal PCLK, the temperature signal ST, and the reference voltage REF correspond to the above-described status information INF.

An operation of the arithmetic circuit 20 in the correction circuit 25 is the same as the operation of the arithmetic circuit 20 in the correction circuit 24, and thus, redundant descriptions thereof are omitted.

Therefore, according to the semiconductor device 400, a single selected correction value CVS corresponding to the operation frequency and the environmental temperature of the semiconductor device 400 can be selected from among the plurality of correction values stored in the non-volatile memory 15. Thus, the semiconductor device 500 can appropriately correct the offset amount in the conversion value DS even when the effects of the operation frequency and effects of the temperature with respect to the offset are not independent of each other.

Other advantages of the semiconductor device 500 are the same as those of the semiconductor devices according to the above-described embodiments, and thus, redundant descriptions thereof are omitted.

### SIXTH EMBODIMENT

In the above-described embodiments, a semiconductor device that selects the correction value used to correct the offset in the conversion value based on the operating status has been described. However, there may be a case where the offset in the conversion value of the A/D converter 1 mounted on the semiconductor device depends on the combination of the semiconductor device and external devices connected to the semiconductor device. Therefore, in the present embodiment, a semiconductor device that selects the correction value according to the connected external devices is described.

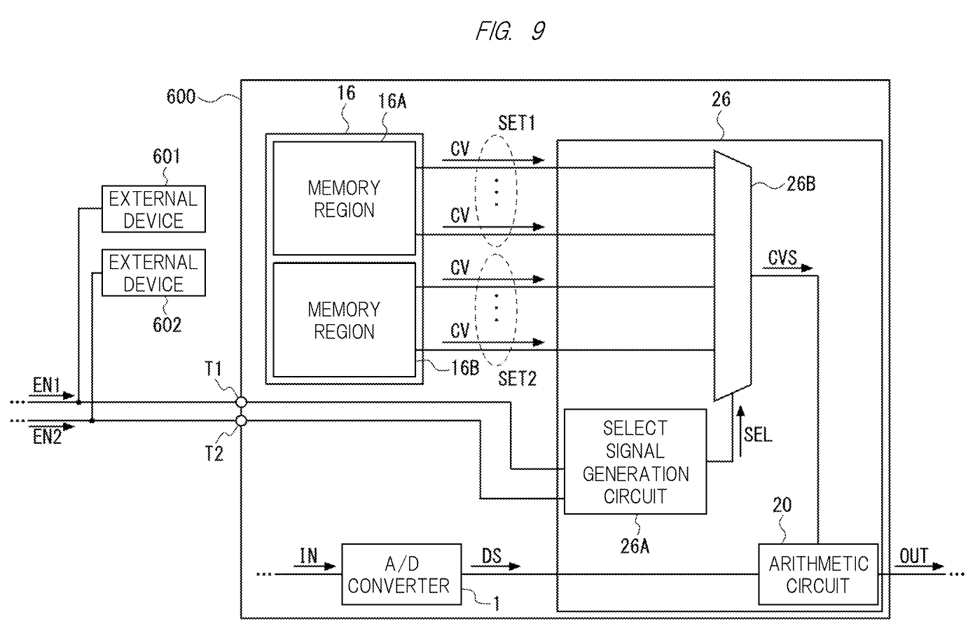

FIG. 9 is a block diagram schematically showing a configuration of a semiconductor device according to the sixth embodiment. In the present embodiment, a semiconductor device 600 is connected to external devices 601 and 602. The external devices 601 and 602 are each supplied with operation enable signals EN1 and EN2 that instruct activation/deactivation, and are activated in a complementary manner. In addition, the operation enable signals EN1 and EN2 are input to enable signal terminals T1 and T2 provided in the semiconductor device 600. In the present embodiment, it is anticipated that the offset in the conversion value DS varies depending on which of the external devices 601 and 602 is activated.

The semiconductor device 600 has a configuration in which the non-volatile memory 11 and the correction circuit 21 of the semiconductor device 100 are respectively replaced with a non-volatile memory 16 and a correction circuit 26.

The non-volatile memory 16 has at least a memory region 16A and a memory region 16B. The memory region 16A stores a correction value set ST1 used when the external device 601 is activated. The memory region 16B stores a correction value set ST2 when the external device 602 is activated.

The correction value corresponding to each of the above-described external devices may be prepared by, for example, the user of the semiconductor device using various methods such as actual measurement or simulation in accordance with the external devices used with the semiconductor device. In this case, as described above, since the optional memory provided in the semiconductor device can be used as the non-volatile memory of the present embodiment, the user can easily store the prepared correction value in the non-volatile memory.

The correction circuit 26 has a select signal generation circuit 26A and a selector 26B. Note that the arithmetic circuit 20 in the correction circuit 26 is the same as the arithmetic circuit 20 in the correction circuit 21.

The select signal generation circuit 26A receives the operation enable signals EN1 and EN2 via the enable signal terminals T1 and T2. Then, the select signal generation circuit 26A generates the select signal SEL indicating the correction value to be selected by the selector 26B based on which of the external devices 601 and 602 is activated. The select signal generation circuit 26A outputs the generated select signal SEL to the selector 26B.

The selector 26B selects a correction value corresponding to the external devices indicated by the select signal SEL from among the plurality of correction values stored in the memory regions 16A and 16B. Here, an example is assumed where the external device 601 is activated. In such a case, the selector 26B outputs the correction value corresponding to the external device 601 and stored in the memory region 16A to the arithmetic circuit 20.

In the present embodiment, the operation enable signals EN1 and EN2 are included in the above-described status information INF.

An operation of the arithmetic circuit 20 in the correction circuit 26 is the same as the operation of the arithmetic circuit 20 in the correction circuit 21, and thus, descriptions thereof are omitted.

Thus, according to the semiconductor device 600, even if the offset in the conversion value DS is affected by the operation of the external devices of the semiconductor device, a suitable correction value can be selected to appropriately correct the offset. As a result, as in the semiconductor device according to the above-described embodiments, the offset in the conversion value of the A/D converter can be automatically corrected. Thus, the semiconductor device 600 can appropriately correct the offset in the conversion value DS to obtain the desired output value OUT.

Other advantages of the semiconductor device 600 are the same as those of the semiconductor devices according to the above-described embodiments, and thus, redundant descriptions thereof are omitted.

### SEVENTH EMBODIMENT

In the above-described embodiments, a semiconductor device that corrects the offset in the conversion value of the mounted A/D converter 1 has been described. However, combining the select signal generation circuit and the selector of the above-described correction circuit and the non-volatile memory makes it possible to correct the offset in the conversion value and adjust an operation of a hard macro mounted on the semiconductor device according to the operating status of the semiconductor device. Therefore, in the present embodiment, a semiconductor device capable of adjusting the operation of the mounted hard macro is described.

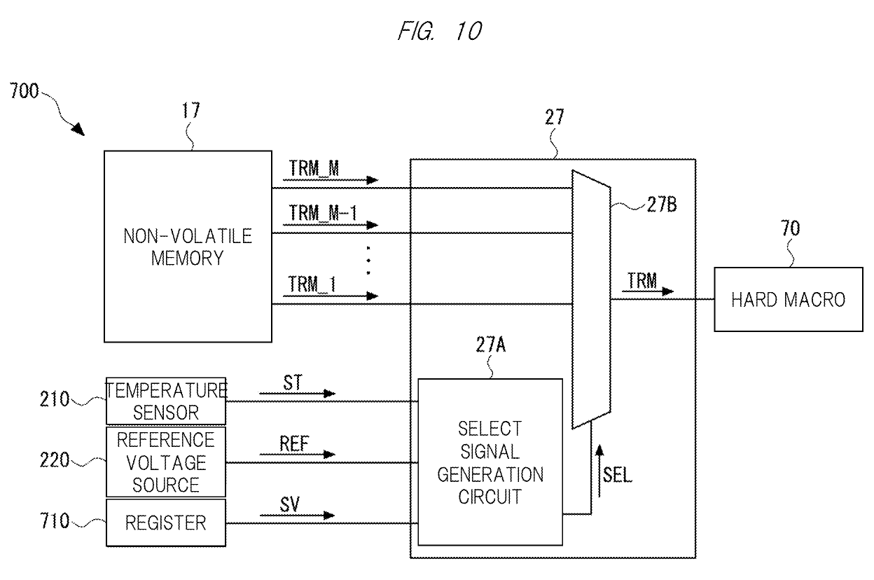

FIG. 10 is a block diagram schematically showing a configuration of a semiconductor device according to a seventh embodiment. A semiconductor device 700 has a configuration in which the non-volatile memory 12 and the correction circuit 22 of the semiconductor device 200 are respectively replaced with a non-volatile memory 17 and a correction circuit 27. In addition, the semiconductor device 700 is provided with a register 710 that holds a value of a power supply voltage VCC supplied to the semiconductor device 700. Further, the semiconductor device 700 is provided with a hard macro 70 that performs various processes and includes a variable element.

The non-volatile memory 17 stores a plurality of trimming values TRM_1 to TRM_M to be provided to the hard macro so as to correspond to the environmental temperature.

The correction circuit 27 has a select signal generation circuit 27A and a selector 27B.

The select signal generation circuit 27A respectively receives the temperature signal ST and the reference voltage REF from the temperature sensor 210 and the reference voltage source 220. The select signal generation circuit 27A compares the temperature signal ST and the reference voltage REF, and detects the temperature TMP indicated by the temperature signal ST. In addition, the select signal generation circuit 27A receives a power supply voltage signal SV indicating a power supply voltage output from the register 710. Note that, in order to determine the power supply voltage, it may be configured such that the power supply voltage is input to the select signal generation circuit 27A. Determining the power supply voltage in the select signal generation circuit 27A in such a manner is merely an example. The select signal generation circuit 27A may determine the power supply voltage using other various methods. The select signal generation circuit 27A outputs the select signal SEL indicating the trimming value to be selected from among the plurality of trimming values stored in the non-volatile memory 17 so as to correspond to the temperature TMP and the power supply voltage indicated by the power supply voltage signal SV to the selector 27B.

The selector 27B selects the trimming value indicated by the select signal SEL from the plurality of trimming values stored in the non-volatile memory 17. Then, the selected trimming value TRM is output to the hard macro 70.

The hard macro 70 performs trimming of, for example, an internal variable element based on a trimming value TMR received from the selector 27B.

As described above, according to the semiconductor device 700, it is possible to adjust hardware such as the hard macro provided in the semiconductor device 700 in response to the operating status of the semiconductor device.

### OTHER EMBODIMENTS

In the foregoing, the disclosure has been described with reference to the embodiments. However, the disclosure is not limited to the foregoing embodiments, and various modifications may be made to the configuration and details of the disclosure within the scope of the disclosure that would be understood by one skilled in the art. Note that each embodiment may be combined with other embodiments as appropriate.

In the fourth and fifth embodiments, examples in which the correction value is selected based on a combination of the operation frequency and the environmental temperature of the semiconductor device have been described. However, the combination of the operating status referenced for selecting the correction value is not limited to this. For example, in the above-described embodiment, in addition to the combinations described above, the semiconductor device may select a correction value based on a combination of some or all types of operating statuses described above, including at least the operation frequency, the environmental temperature, and the conversion value after A/D conversion.

In the above-described embodiments, the semiconductor device according to the disclosure has been described mainly as a hardware configuration, but it is not limited thereto. The semiconductor device according to the disclosure can be realized by executing a computer program on a computer to perform a desired process. These processes may be realized by executing a program on a computer including at least one processor (e.g., microprocessor, CPU, GPU, MPU, DSP (Digital Signal Processor)). Specifically, one or more programs including a set of instructions for causing a computer to perform an algorithm related to transmission signal processing or reception signal processing may be created and supplied to the computer.

The computer program may be stored using any type of non-transitory computer-readable medium to be fed to a computer. The non-transitory computer-readable medium includes various types of tangible storage media. By way of example but not limiting, the non-transitory computer-readable medium includes a magnetic storage medium (e.g., flexible disk, magnetic tape, hard disk drive), a magneto-optical storage medium (e.g., magneto-optical disk), a CD-ROM (Read Only Memory), a CD-R, a CD-RW, a semiconductor memory (e.g., mask ROM, PROM (programmable ROM), an EPROM (erasable PROM), a flash ROM, and a RAM (random access memory). In addition, the program may be supplied to the computer via various types of transitory computer-readable media. By way of example but not limiting, the transitory computer-readable medium includes an electrical or optical signal, and an electromagnetic wave. The transitory computer-readable medium can supply a program to the computer via a wired communication path such as an electric wire and an optical fiber, or via a wireless communication path.

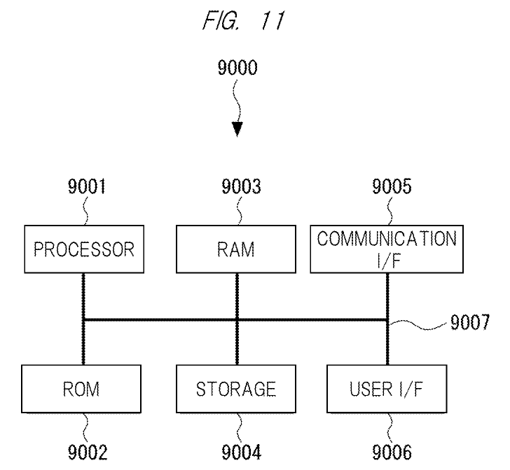

A configuration example of a computer for realizing the semiconductor device according to the above-described embodiments will now be described. FIG. 11 is a diagram showing the configuration example of the computer for realizing the semiconductor device. The semiconductor device can be realized by a computer 9000 such as a dedicated computer or a personal computer (PC). However, the computer does not need to be physically single, and may be multiple when performing distributed processing. As shown in FIG. 11, the computer 9000 has, for example, a processor 9001, a ROM (Read Only Memory) 9002, a RAM (Random Access Memory) 9003, a storage 9004, a communication interface 9005, and a user interface 9006.

The processor 9001, the ROM 9002, the RAM 9003, the storage 9004, the communication interface 9005, and the user interface 9006 are interconnected via a bus 9007 for mutual communication. Note that the OS software and other components necessary to operate the computer are omitted from this description but may be appropriately implemented in the computer 9000.

The ROM is constituted by, for example, a non-volatile semiconductor memory device. The ROM 9002 stores information such as various programs used in the computer 9000.

The storage 9004 is constituted by various storage devices, such as a hard disk or a solid-state disk. In addition, the storage 9004 is not limited to a storage device installed in the computer 9000, and may also be an external storage device. The external storage device may include various communication means such as a cloud storage connected to the computer 9000 via a network. The storage 9004 stores information such as various programs and data used by the computer 9000.

The RAM 9003 is constituted by a volatile semiconductor storage device. The program and data information used by the processor 9001 is appropriately loaded from one or both of the ROM 9002 and the storage 9004 to the RAM 9003.

The processor 9001 may be constituted by, for example, a CPU (Central Processing Unit) or the like. In addition, the processor 9001 may be provided with a GPU (Graphics Processing Unit) in addition to the CPU. The GPU is suitable for performing standardized processing in parallel and can improve processing speed compared to the CPU when used for applications such as processing for a neural network or the like. The processor 9001 appropriately executes various processing operations based on various programs stored in the ROM 9002 or various programs and data held in the RAM 9003. In addition, the processor 9001 may appropriately store data generated during processing in the RAM 9003 or the storage 9004.

The communication interface 9005 is an interface that connects the computer 9000 and a communication network such as the Internet or an intranet via various wired or wireless communication means. Thus, the computer 9000 can communicate with other devices, systems, and sensors connected to the communication network.

The user interface 9006 includes a display that provides information that can be recognized by a user by, for example, means of a display device, and a voice output unit that outputs voice. In addition, the user interface 9006 includes an input unit that allows a user to input information to the computer 9000 by operating a keyboard, a mouse, a touch panel, or the like. In addition, the user interface 9006 may include devices such as sensors that acquire information useful to the user.

Here, the computer 9000 has been described as a single device, but this is merely an example. The computer 9000 may be constituted by a plurality of physically separated devices. Some of the devices may be portable, while others may be stationary.

Each of the drawings is merely an example for describing one or more embodiments. Each of the drawings is not necessarily associated with only one specific embodiment, but may also be associated with one or more other embodiments. As will be understood by one skilled in the art, various features or steps described with reference to any of the drawings can be combined with a feature or step shown in one or more other drawings to create an embodiment not explicitly illustrated or described. Not all features or steps shown in any of the drawings for describing the exemplary embodiment are necessarily required, and some features or steps may be omitted. The order of steps described in any of the drawings may be changed as appropriate.

What is claimed is:

1. A semiconductor device comprising:
an analogue to digital converter configured to output a conversion value obtained by performing analogue to digital conversion on an input signal;
a non-volatile memory configured to store a plurality of correction values; and
a correction circuit configured to select, in response to a status affecting an offset in the conversion value of the analogue to digital converter, a correction value corresponding to the status from among the plurality of correction values as a selected correction value, and to output an output value in which the offset in the conversion value is corrected based on the selected correction value.

2. The semiconductor device according to claim 1,
wherein the correction circuit comprises:
a select signal generator configured to receive information indicating the status and to generate a select signal indicating a correction value to be selected from among the plurality of correction values based on the information;
a selector configured to output the correction value indicated by the select signal from the non-volatile memory as the selected correction value; and
an arithmetic circuit configured to output the output value in which the offset in the conversion value is corrected based on the selected correction value.

3. The semiconductor device according to claim 1,
wherein the non-volatile memory is configured to store the plurality of correction values each corresponding to a frequency of a clock signal for controlling an operation of the semiconductor device, and
wherein the correction circuit is configured to select a correction value corresponding to the frequency of the clock signal as the selected correction value.

4. The semiconductor device according to claim 3,
wherein the non-volatile memory is configured to store the plurality of correction values each corresponding to a combination of a frequency of a first clock signal for controlling the operation of the semiconductor device and a frequency of a second clock signal for controlling an analogue to digital conversion operation of the analogue to digital converter, and
wherein the correction circuit is configured to select a correction value corresponding to the combination of the frequency of the first clock signal and the frequency of the second clock signal as the selected correction value.

5. The semiconductor device according to claim 1,
wherein the non-volatile memory is configured to store the plurality of correction values each corresponding to the temperature of the semiconductor device, and
wherein the correction circuit is configured to select a correction value corresponding to the temperature as the selected correction value.

6. The semiconductor device according to claim 1,
wherein the non-volatile memory is configured to store the plurality of correction values each corresponding to the input signal of the analogue to digital converter, and
wherein the correction circuit is configured to select a correction value corresponding to the input signal of the analogue to digital converter as the selected correction value.

7. The semiconductor device according to claim 1,
wherein the plurality of correction values include some or all of: a first set of correction values corresponding to a combination of a frequency of a first clock signal for controlling an operation of the semiconductor device and a frequency of a second clock signal for controlling an analogue to digital conversion operation of the analogue to digital converter; a second set of correction values corresponding to the temperature of the semiconductor device; and a third set of correction values corresponding to the conversion value of the analogue to digital converter, and
wherein the correction circuit is configured to select one, two, or three correction values selected from some or all of the first to third sets corresponding to some or all of the combination of the frequencies, the temperature, and the conversion value of the analogue to digital converter as the selected correction value.

8. The semiconductor device according to claim 1,
wherein each of the plurality of correction values is a correction value corresponding to some or all of: a combination of a frequency of a first clock signal for controlling an operation of the semiconductor device and a frequency of a second clock signal for controlling an analogue to digital conversion operation of the analogue to digital converter; the temperature of the semiconductor device; and the conversion value of the analogue to digital converter, and
wherein the correction circuit is configured to select the selected correction value from among the plurality of correction values in accordance with some or all of the combination of the frequencies, the temperature, and the conversion value of the analogue to digital converter.

9. The semiconductor device according to claim 1,
wherein the plurality of correction values include a plurality of correction value sets corresponding to a plurality of external devices, and
wherein the correction circuit is configured to select the selected correction value corresponding to a single external device among the plurality of external devices from among the plurality of correction value sets.

10. A method for correcting a conversion value of the analogue to digital converter, comprising the steps of:
outputting a conversion value obtained by performing analogue to digital conversion on an input signal;
selecting, in response to a status affecting an offset in the conversion value, a correction value corresponding to the status from among a plurality of correction values stored in a non-volatile memory; and
outputting an output value in which the offset in the conversion value is corrected based on the selected correction value.

11. A program configured to cause a computer to perform:
a process of selecting, in response to a status affecting an offset in a conversion value obtained by performing analogue to digital conversion on an input signal using an analogue to digital converter, a correction value corresponding to the status from among a plurality of correction values stored in a non-volatile memory; and
a process of outputting an output value in which the offset in the conversion value is corrected based on the selected correction value.
